(19) United States
(12) Patent Application Publication
(10) Pub. No.: US 2018/0278160 A1
(43) Pub. Date: Sep. 27, 2018

(54) Method and Apparatus to Facilitate Calibrating a Loop Error Amplifier in an Integrated Circuit

(71) Applicant: Texas Instruments Incorporated, Dallas, TX (US)

(72) Inventors: Michael James Munroe, Londonderry, NH (US); Stephen Isaac Brink, Manchester, NH (US)

(21) Appl. No.: 15/927,442

(22) Filed: Mar. 21, 2018

Related U.S. Application Data
(60) Provisional application No. 62/475,044, filed on Mar. 22, 2017.

(51) Int. Cl. H02M 3/158; H02M 1/088; H03M 1/12

(52) U.S. Cl. CPC H02M 3/158; H02M 2001/0012; H03M 1/124; H02M 1/088

(57) ABSTRACT

An integrated circuit having at least one electrically-controlled control loop that includes one or more loop error amplifiers also includes an analog-to-digital converter having both an input that operably couples to two inputs of each loop error amplifier and an output that couples to an off-chip hardware component comprising a control circuit. This control circuit reads digital versions that correspond to the loop error amplifier inputs. When a particular first input is greater than a second input, the control circuit sources a calibration signal to modify and offset for the loop error amplifier in a first direction. When the first input is less than the second input, the control circuit sources a calibration signal to modify the offset for the loop error amplifier in a second direction that is different from the aforementioned first direction. By one approach the control circuit also controls a sampling rate of the analog-to-digital converter.

### RELATED APPLICATION(S)

This application claims the benefit of U.S. Provisional application No. 62/475,044, filed Mar. 22, 2017, which is incorporated by reference in its entirety herein.

### TECHNICAL FIELD

These teachings relate generally to the calibration of on-chip components in an integrated circuit.

### BACKGROUND

An integrated circuit (IC) typically comprises a set of electronic circuits on a single piece of semiconductor material such as a silicon substrate. These circuits may include a variety of active and passive components. Fabrication techniques for integrated circuits are extremely precise and well controlled, but for a variety of reasons, it may be very difficult to replicate integrated circuits that are exactly identical to one another. Instead, in the absence of any corrective action, a given circuit in a particular integrated circuit can have varying performance from one IC to another.

For example, control loops typically need to act and react in a highly consistent and predictable manner. The aforementioned performance variations can therefore lead to performance issues related to control loops. In addition, some circuit components introduce offsets that can negatively impact the desired operability of a control loop.

### SUMMARY

The present disclosure introduces an integrated circuit that includes at least one electrically-controlled control loop. This electrically-controlled control loop includes at least one loop error amplifier. This electrically-controlled control loop also includes an analog-to-digital converter. The analog-to-digital converter has an input and an output. The input selectively operably couples to at least two inputs of the aforementioned loop error amplifier. The output is operably accessible to an off-chip hardware component.

These teachings are flexible in practice and will accommodate electrically-controlled control loops having two or more loop error amplifiers (that each typically have two inputs). In this case the aforementioned analog-to-digital converter can selectively couple (for example, via a multiplexor) to both inputs for each such loop error amplifier.

By one approach the aforementioned off-chip hardware component comprises a control circuit that operably couples to the analog-to-digital converter. This control circuit can be configured to read digital versions that correspond to the inputs to the loop error amplifier(s). By one approach the control circuit compares these digital versions against one another. When a first input to the loop error amplifier is greater than a second input to the loop error amplifier, the control circuit sources a calibration signal. This calibration signal can serve to modify an offset for the loop error amplifier in a first direction (such as, for example, in a negative direction). When the first input to the loop error amplifier is less than the second input to the loop error amplifier, the control circuit sources a different calibration signal. This different calibration signal serves to modify the offset for the loop error amplifier in a second direction (such as, for example, in a positive direction) that is different from the aforementioned first direction.

By one approach, and if desired, the aforementioned control circuit can be further configured to control a sampling rate of the analog-to-digital converter. For example, the control circuit can be configured to use a first sampling rate for the analog-to-digital converter when sampling a first one of two loop error amplifiers. The control circuit can also be configured to use a second sampling rate that is different from the first sampling rate when sampling a second one of the two loop error amplifiers. For example, the first sampling rate can be faster than the second sampling rate. Such an approach can be particularly useful when the first loop error amplifier comprises a current loop error amplifier while the second loop error amplifier comprises a voltage loop error amplifier.

So configured, loop error amplifiers can be readily and accurately calibrated at a point of manufacture using a combination of on-chip and off-chip components. The number of on-chip components that are uniquely dedicated to the calibration functionality are minimal, thereby helping to ensure that only minimal on-chip space and materials are necessary. For example, the aforementioned on-chip analog-to-digital converter can serve other needs in post-manufacture and end user-based settings.

### BRIEF DESCRIPTION OF THE DRAWINGS

FIG. 1 comprises a schematic diagram of a circuit in accordance with an aspect of the present disclosure;

FIG. 2 comprises a flow diagram in accordance with an aspect of the present disclosure;

FIG. 3 comprises a flow diagram in accordance with an aspect of the present disclosure; and

FIG. 4 comprises a schematic diagram of a circuit in accordance with an aspect of the present disclosure.

Elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present teachings. Also, common but well-understood elements that are useful or necessary in a commercially feasible embodiment are often not depicted in order to facilitate a less obstructed view of these various embodiments of the present teachings. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein.

### DETAILED DESCRIPTION

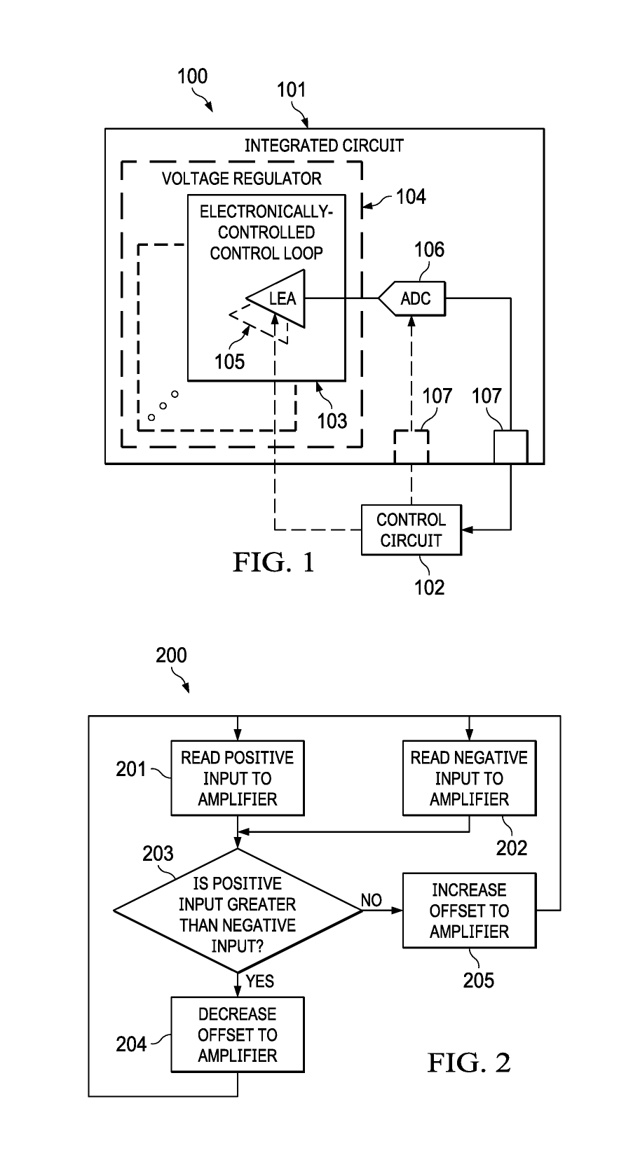

Referring now to the drawings, and in particular to FIG. 1, an integrated circuit 101 (which may be viewed as comprising a part of a larger apparatus 100) that is compatible with many of these teachings will now be presented.

For the sake of an illustrative example, the remainder of this description presumes that the apparatus 100 comprises a control loop automatic zeroing apparatus that makes use of both the integrated circuit 101 and an off-chip control circuit 102. A control loop automatic zeroing apparatus is a circuit that eliminates (or nearly eliminates) a voltage and/or current offset in a control loop by reducing the offset to zero (or nearly zero).

The integrated circuit 101 comprises various mixed-signal components (i.e., both analog and digital circuitry) and specifically includes one or more electronically-controlled control loops 103 that may comprise a part, for example, of a voltage regulator 104 that is itself a part of a switched-mode power supply. To be clear, the aforementioned off-chip control circuit 102 is not a part of these control loops 103.

This description also presumes, and again for the sake of an illustrative example, one or more loop error amplifiers 105 that comprise a part of the aforementioned electronically-controlled control loop 103. These loop error amplifiers 105 may comprise two-input differential amplifiers that are connected in a feedback configuration to detect loop errors and control the regulator's 104 operation to eliminate or at least minimize those errors to thereby achieve an output that matches a target. This (or these) loop error amplifier(s) 105 may comprise, for example, a voltage loop error amplifier and/or a current loop error amplifier.

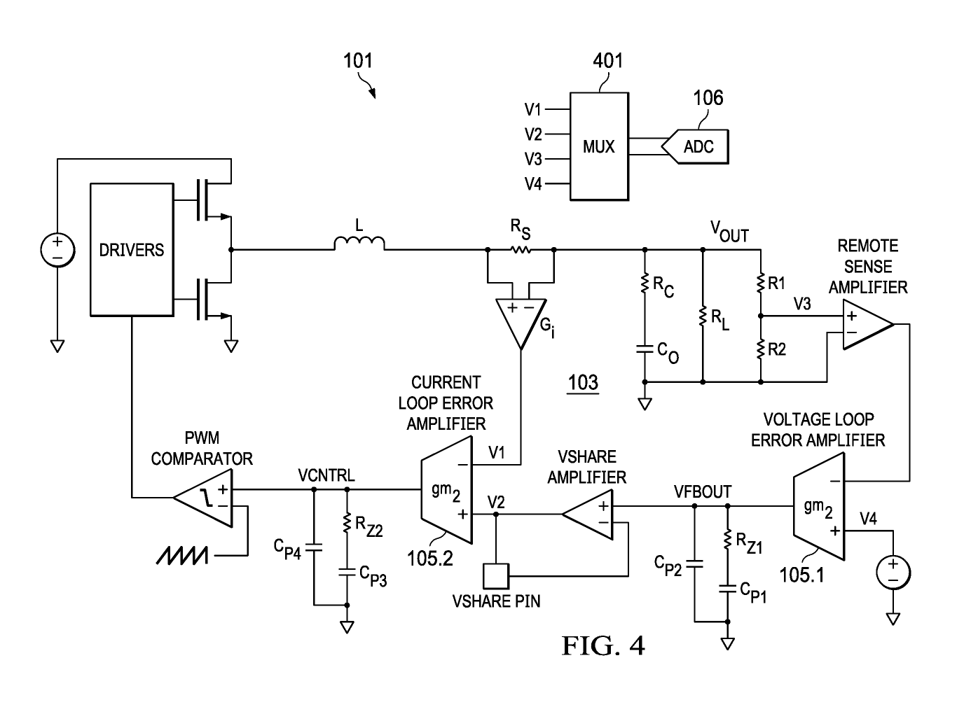

In addition to the foregoing, the integrated circuit 101 also includes an analog-to-digital converter 106. By one approach this analog-to-digital converter 106 comprises a Delta-Sigma analog-to-digital converter. In this illustrative example the analog-to-digital converter 106 has an input that selectively operably couples to at least two inputs for each of the loop error amplifiers 105 (as shown below in more detail in FIG. 4). The analog-to-digital converter 106 operably couples to one or more contact pads 107. So configured, the analog-to-digital converter 106 output is operably accessible (via such a contact pad 107) to at least one off-chip hardware component (i.e., a component that is off, and does not comprise a part of, the aforementioned integrated circuit 101), in this case the aforementioned off-chip control circuit 102.

The control circuit 102 comprises structure that includes at least one (and typically many) electrically-conductive paths (e.g., paths comprised of a conductive metal such as copper or silver) that conduct electricity. These path(s) will also typically include corresponding electrical components (both passive (such as resistors and capacitors) and active (such as any of a variety of semiconductor-based devices) as appropriate) to permit the circuit to effect the control aspect of these teachings.

Such a control circuit 102 can comprise a fixed-purpose hard-wired hardware platform (including but not limited to an application-specific integrated circuit (ASIC) (which is an integrated circuit that is customized by design for a particular use, rather than intended for general-purpose use), a field-programmable gate array (FPGA), and the like) or can comprise a partially or wholly-programmable hardware platform (including but not limited to microcontrollers, microprocessors, and the like). These architectural options for such structures are well known and understood in the art and require no further description here. This control circuit 102 is configured (for example, by using corresponding programming as will be well understood by those skilled in the art) to carry out one or more of the steps, actions, and/or functions described herein.

By one optional approach the control circuit 102 operably couples to a memory. This memory may be integral to the control circuit 102 or can be physically discrete (in whole or in part) from the control circuit 102 as desired. This memory can also be local with respect to the control circuit 102 (where, for example, both share a common circuit chip, chassis, power supply, and/or housing) or can be partially or wholly remote with respect to the control circuit 102 (where, for example, the memory is physically located in another facility, metropolitan area, or even country as compared to the control circuit 102).

This memory can serve, for example, to non-transitorily store the computer instructions that, when executed by the control circuit 102, cause the control circuit 102 to behave as described herein. (As used herein, this reference to “non-transitorily” will be understood to refer to a non-ephemeral state for the stored contents (and hence excludes when the stored contents merely constitute signals or waves) rather than volatility of the storage media itself and hence includes both non-volatile memory (such as read-only memory (ROM) as well as volatile memory (such as an erasable programmable read-only memory (EPROM).)

In this illustrative example the apparatus 100 is generally configured to calibrate the electrically-controlled control loop 103 in the integrated circuit 101 and more specifically to calibrate the loop error amplifiers 105 that comprise a part of such an electronically-controlled control loop 103. FIG. 2 presents a general process 200 in these regards.

Generally speaking, on a per amplifier basis, the aforementioned control circuit 102 reads the positive input to a given loop error amplifier 105 at block 201 and reads the negative input to that same amplifier 105 at block 202. At block 203 the control circuit 102 then detects whether and when the aforementioned positive input is greater than the negative input. When true, at block 204 the control circuit 102 decreases an offset to the loop error amplifier 105. When false, at block 205 the control circuit 102 increases the offset to the loop error amplifier 105.

By one approach, the aforementioned decreases/increases to the offset can comprise corresponding adjustments (such as voltage-based adjustments) to a trimmed offset for the corresponding loop error amplifier 105. Trimming constitutes a well understood prior art endeavor and persons skilled in the art will recognize and understand that trimming is done as a production step during fabrication of the integrated circuit (rather than, for example, a dynamic activity that occurs during post-manufacturing ordinary use of the integrated circuit).

Those skilled in the art will appreciate that the above-described approach avoids needing to break the loop being calibrated during the calibration process.

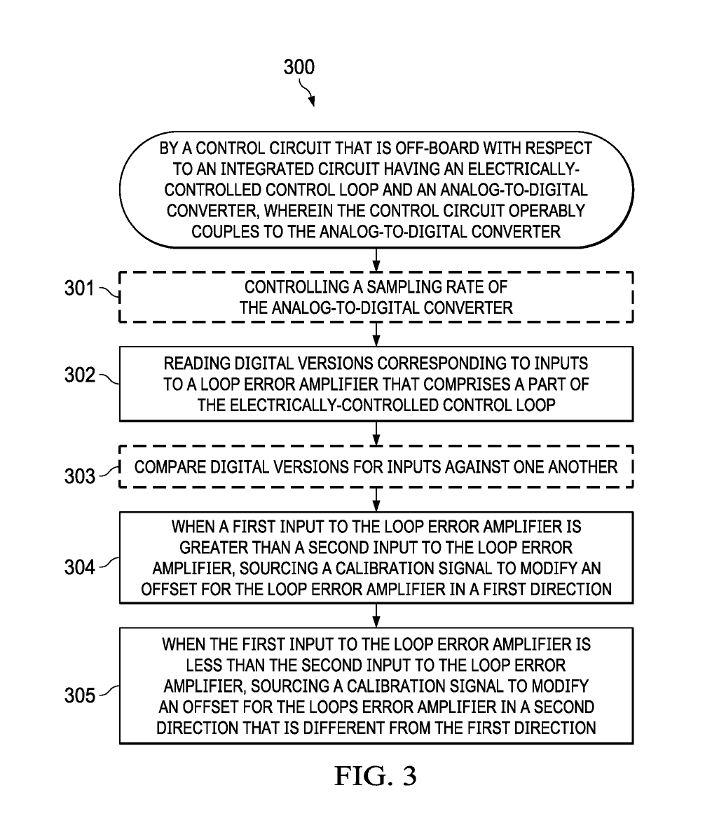

FIG. 3 provides a somewhat more detailed description of a process 300 that corresponds to the foregoing teachings. In this illustrative example a control circuit that is off-chip with respect to an integrated circuit having an electrically-controlled control loop and an analog-to-digital converter and wherein the control circuit operably couples to the analog-to-digital converter (and optionally to one or more components that comprise a part of the electrically-controlled control loop) carries out this process 300.

By one optional approach, and as illustrated at optional block 301, the aforementioned control circuit 102 controls a sampling rate of the analog-to-digital converter 106. For example, when the electrically-controlled control loop 103 includes a first and a second loop error amplifier 105, the control circuit can be configured to use a first sampling rate for the analog-to-digital converter 106 when sampling a first one of the error amplifiers 105 and a second sampling rate that is different than the first sampling rate for the analog-to-digital converter 106 when sampling the second one of the loop error amplifiers 105.

Such an approach can be helpful and beneficial when, for example, one of the loop error amplifiers 105 comprises a current loop error amplifier and another of the loop error amplifiers 105 comprises a voltage error amplifier. In that case, the control circuit 102 can employ a first sampling rate that is faster when sampling the current loop error amplifier and a second sampling rate that is lower when sampling the voltage loop error amplifier. Such an approach can help to accommodate low bandwidth requirements of the corresponding automatic-zeroing loop by effectively dynamically scaling the bandwidth using this technique.

At block 302 the control circuit 102 reads digital versions corresponding to at least two inputs (such as the positive input and the negative input) of at least a first loop error amplifier 105 that comprises a part of the electrically-controlled control loop 103. These digital versions comprise digital representations/conversions of the sensed analog levels at these inputs at a particular desired sampling resolution. As noted above, these digital versions can optionally be based upon a selectively controlled analog-to-digital conversion sampling rate depending upon which loop error amplifier 105 is presently being sampled.

In a typical application setting, and as illustrated at optional block 303, the control circuit 102 compares the foregoing digital versions against one another to facilitate detecting and identifying any variations there between.

At block 304, when a first input to the selected loop error amplifier 105 (such as the positive input) is greater than a second input to the loop error amplifier 105 (such as the negative input), the control circuit 102 sources a calibration signal to modify a corresponding offset for the loop error amplifier 105 in a first direction (such as a negative direction that would accordingly decrease the offset). Alternatively, at block 305, when the first input to the loop error amplifier 105 is less than the second input to the loop error amplifier 105, the control circuit 102 sources a calibration signal to modify the offset for the loop error amplifier 105 in a second direction that is different from the aforementioned first direction (such as a positive direction that will accordingly increase the offset).

The amount of incremental decrease/increase of the offset per the foregoing can be selected as desired. Generally speaking, the step size used in a particular application setting can comprise a balance of speed and accuracy. The larger the step size, the faster the final value will be reached albeit usually with less accuracy.

FIG. 4 presents a more detailed illustrative example in these regards. It will be understood that the specifics of this example are intended to serve an illustrative purpose and are not intended to suggest any particular limitations in these regards. In this illustrative example the integrated circuit 100 has an electronically-controlled control loop 103 that comprises a high current buck converter that makes use of average current mode control. Accordingly, this electronically-controlled control loop 103 includes both a voltage loop error amplifier 105.1 and a current loop error amplifier 105.2. Such an electronically-controlled control loop 103 is known in the art and does not require further elaboration here.

In this example, and per these teachings, the integrated circuit 101 also includes an analog-to-digital converter 106 having an input that couples to an appropriate multiplexer 401 configured, in this example, to receive four inputs denoted as V1 through V4. These inputs correspond to the loop error amplifier inputs described above. In particular, V1 corresponds to the negative input of the current loop error amplifier 105.2, V2 corresponds to the positive input of the current loop error amplifier 105.2, V3 corresponds to the positive input of a remote sense amplifier which readily translates to and serves to represent the negative input of the voltage loop error amplifier 105.1, and V4 corresponds to the positive input of the voltage loop error amplifier 105.1. So configured, the analog-to-digital converter 106 can read and convert, in seriatim fashion, analog signals corresponding to the inputs of the loop error amplifiers 105 that comprise the electrically-controlled control loop 103 per these teachings. As described above, the digitized representations can then be provided to the control circuit 102 to effect the actions described herein.

As noted above, there are various ways to effect the desired training activity. In the present case, such training can be accomplished by, for example, adjusting an appropriate voltage source (such as V4 in FIG. 4 which serves as an accurate point of reference and/or an input voltage to the converter 106).

These teachings are useful in most if not all electrically-controlled closed-loop systems. Such systems typify many voltage regulator architectures including but not limited to voltage regulators that include switching power converters.

In a typical application setting the foregoing input sensing and responsive training can occur relatively slowly. A slower rather than a faster response will often better accommodate the operating dynamics of the control loop. In the circuit illustrated in FIG. 4, for example, the switching power converter has a Nyquist rate equal to half the switching frequency. The current loop error amplifier 105.2 therefore should crossover at a theoretical maximum of the switching frequency divided by two. The voltage loop error amplifier 105.1, in turn, should crossover at one half of the current loop amplifier 105.2 rate (such that the voltage loop error amplifier 105.1 must crossover at a theoretical maximum of the switching frequency divided by four). In practice, it can be beneficial to use even slower rates than these theoretical maximums. Accordingly, and as illustrative examples in these regards, useful sampling can provide for sampling measures only at every 20^{th} switching cycle or even only at every 100^{th} switching cycle.

Various calibration techniques are known to permit adjusting the performance of such a circuit at the time of manufacture. Such techniques can serve, for example, to counter an offset introduced by another component or circuit. Known techniques in these regards, however, are not always fully sufficient to meet the needs of a given application setting. Control loops for switching power converters, for example, can have a power converter that employs a switching frequency that scales more than an order of magnitude. Such a power converter may present particular challenges including a relatively low bandwidth for the control loop. A low bandwidth control loop may force a typical prior art calibration mechanism to break the control loop momentarily from time to time. The applicant has determined that such a phenomena may be unacceptable for a switching power converter that should preferably maintain regulation of the loop. Pursuant to the approaches described herein, however, an electronically-controlled control loop can be auto-zeroed in a continuous manner and without having to be broken in order to accomplish desired calibration. The resultant calibration, in turn, can facilitate best-in-class performance of the loop in terms of overall functionality.

Furthermore, it will be appreciated that use of these teachings allows for lower transconductance when employing transconductance amplifiers. This, in turn, allows for smaller capacitors on internally compensated products, thereby requiring less die area and further reducing the cost of the integrated circuit.

Those skilled in the art will recognize that a wide variety of modifications, alterations, and combinations can be made with respect to the above described embodiments without departing from the scope of the invention. As but one example in these regards, other accurate analog measurement techniques can be combined with digital sampling in lieu of the above-described Delta-Sigma analog-to-digital converter 106. Accordingly it will be understood that such modifications, alterations, and combinations are to be viewed as being within the ambit of the inventive concept.

What is claimed is:

1. An integrated circuit comprising:
an electrically-controlled control loop that includes a loop error amplifier;
an analog-to-digital converter having an input that selectively operably couples to two inputs of the loop error amplifier and an output; and
a contact pad that is operably coupled to the output of the analog-to-digital converter such that the analog-to-digital converter is operably accessible to an off-chip hardware component.

2. The integrated circuit of claim 1 wherein the electrically-controlled control loop comprises a part of a voltage regulator.

3. The integrated circuit of claim 2 wherein the voltage regulator comprises a part of a switched-mode power supply.

4. The integrated circuit of claim 1 wherein the electrically-controlled control loop further comprises a second loop error amplifier, and where the analog-to-digital converter input further selectively operably couples to two inputs of the second loop error amplifier.

5. The integrated circuit of claim 4 wherein the loop error amplifier comprises a voltage loop error amplifier and the second loop error amplifier comprises a current loop error amplifier.

6. A control loop automatic zeroing apparatus comprising:
an integrated circuit having an electrically-controlled control loop and an analog-to-digital converter having an input that selectively operably couples to two inputs of a loop error amplifier that comprises a part of the electrically-controlled control loop;
a control circuit that is off-chip with respect to the integrated circuit and that operably couples to the analog-to-digital converter, wherein the control circuit is configured to:
read digital versions corresponding to the two inputs of the loop error amplifier;
when a first input to the loop error amplifier is greater than a second input to the loop error amplifier, sourcing a calibration signal to modify an offset for the loop error amplifier in a first direction;
when the first input to the loop error amplifier is less than the second input to the loop error amplifier, sourcing a calibration signal to modify an offset for the loop error amplifier in a second direction that is different from the first direction.

7. The control loop automatic zeroing apparatus of claim 6 wherein the first input comprises a positive input and the second input comprises a negative input and wherein the first direction is a negative direction and the second direction is a positive direction.

8. The control loop automatic zeroing apparatus of claim 6 wherein the loop error amplifier comprises one of a voltage loop error amplifier and a current loop error amplifier.

9. The control loop automatic zeroing apparatus of claim 6 wherein the control circuit is further configured to control a sampling rate of the analog-to-digital converter.

10. The control loop automatic zeroing apparatus of claim 9 wherein the electrically-controlled control loop further comprises a second loop error amplifier and the input of the analog-to-digital converter further selectively operably couples to two inputs of the second loop error amplifier, and wherein the control circuit is configured to read digital versions corresponding to the inputs of both of the loop error amplifiers and to use a first sampling rate for the analog-to-digital converter when sampling the loop error amplifier and a second sampling rate that is different than the first sampling rate for the analog-to-digital converter when sampling the second loop error amplifier.

11. The control loop automatic zeroing apparatus of claim 10 wherein the loop error amplifier comprises a current loop error amplifier and the second loop error amplifier comprises a voltage loop error amplifier.

12. The control loop automatic zeroing apparatus of claim 11 wherein the first sampling rate is faster than the second sampling rate.

13. A method to facilitate calibrating an electrically-controlled control loop in an integrated circuit having the electrically-controlled control loop and an analog-to-digital converter having an input that selectively operably couples to two inputs of a loop error amplifier that comprises a part of the electrically-controlled control loop, the method comprising:
by a control circuit that is off-chip with respect to the integrated circuit and that operably couples to the analog-to-digital converter:
reading digital versions corresponding to the inputs to the loop error amplifier;
when a first input to the loop error amplifier is greater than a second input to the loop error amplifier, sourcing a calibration signal to modify an offset for the loop error amplifier in a first direction;
when the first input to the loop error amplifier is less than the second input to the loop error amplifier, sourcing a calibration signal to modify an offset for the loop error amplifier in a second direction that is different from the first direction;
such that the electronically-controlled control loop is auto-zeroed in a continuous manner and without breaking the control loop.

14. The method of claim 13 further comprising:
controlling a sampling rate of the analog-to-digital converter.

15. The method of claim 14 wherein controlling the sampling rate of the analog-to-digital converter comprises using a first sampling rate for the analog-to-digital converter when sampling a first loop error amplifier and a second sampling rate that is different than the first sampling rate for the analog-to-digital converter when sampling a second loop error amplifier.
